(19) United States
(12) Patent Application Publication
(10) Pub. No.: US 2015/0017409 A1
(43) Pub. Date: Jan. 15, 2015

(54) COMPOSITE MEMBER

(71) Applicant: Hitachi, Ltd., Tokyo (JP)

(72) Inventors: Takashi Naito, Tokyo (JP); Tadashi Fujieda, Tokyo (JP); Takuya Aoyagi, Tokyo (JP); Yuichi Sawai, Tokyo (JP); Hajime Murakami, Tokyo (JP); Masahiko Ogino, Tokyo (JP); Akihiro Miyauchi, Tokyo (JP); Hiroshi Yoshida, Tokyo (JP)

(73) Assignee: Hitachi, Ltd., Tokyo (JP)

(21) Appl. No.: 14/367,744

(22) PCT Filed: Nov. 21, 2012
(86) PCT No.: PCT/JP2012/080119

§ 371 Date: Jun. 20, 2014

(30) Foreign Application Priority Data
Dec. 26, 2011 (JP) 2011-282622

(51) Int. Cl. B05D 3/06; C03C 8/10; H05K 1/18; H05K 1/03; H01L 31/048; B05D 1/12

(52) U.S. Cl. CPC B05D 3/06; H01L 31/0481; B05D 1/12; H05K 1/181; H05K 1/0306; C03C 8/10
USPC 428/216; 428/426; 428/336; 136/256; 416/241 R; 427/553; 427/554; 361/746

(57) ABSTRACT

The gas barrier property of a laminate constituted by a base material containing a resin or a rubber and an oxide glass is improved. A composite member containing an oxide glass 2 formed as a layer densely on a base material 1 containing a resin or a rubber, in which the oxide glass is bonded to the base material by irradiating the oxide glass with an electromagnetic wave and softening and fluidizing the oxide glass.

### TECHNICAL FIELD

This invention relates to a composite member containing an oxide glass formed as a layer on a base material containing a resin or a rubber.

### BACKGROUND ART

There is a wide range of organic compounds, and organic compounds have characteristics in that their functions, physical characteristics and the like are easier to control depending on purpose and they are lighter and easier to form at a relatively low temperature compared with other materials; however, they have defects such as the low gas barrier property, absorbency, odor-absorbing property, deterioration by the irradiation with ultraviolet rays and low mechanical strength (softness). On the other hand, glass is excellent in mechanical strength and chemical stability compared with organic compounds and it is possible to add various functions; however, glass has defects in that glass is heavy and weak to impact and breaks easily. Therefore, various composite materials combining an organic compound and glass have been invented to comprehend each other's defects.

As laminates of glass, an oxide or a nitride and an organic polymer (such as a gas barrier sheet), many laminates obtained by forming a thin film of an oxide or a nitride on an organic polymer film such as polyester or polyamide by a method such as sputtering, vapor deposition, CVD or sol-gel method have been proposed.

PTL1 discloses a gas barrier laminate in which a barrier layer comprising a metal or an inorganic compound and an organic layer comprising an organic compound have been sequentially laminated on at least one surface of a polymer film and in which the barrier layer has been formed using vacuum vapor deposition method.

### CITATION LIST

### Patent Literature

PTL 1: JP-A-2008-265255

### SUMMARY OF INVENTION

### Technical Problem

When a laminate is produced by vapor deposition method, sputtering method and CVD method described above, there are problems in that a small amount of gas may still permeate because only a film with a thickness of dozens of nanometers can be generally formed and the film is not completely dense.

An object of this invention is to improve the gas barrier property.

### Solution to Problem

In order to solve the above problems, this invention is characterized by a composite member containing an oxide glass formed as a layer densely on a base material containing a resin or a rubber, in which the oxide glass is bonded to the base material by irradiating the oxide glass with an electromagnetic wave and softening and fluidizing the oxide glass.

Further, this invention is characterized by containing a step of coating an oxide glass powder on a base material containing a resin or a rubber, a step of applying an electromagnetic wave and a step of forming a layered and dense coated film on the base material by softening and fluidizing the oxide glass powder, and characterized in that the oxide glass contains a transition metal oxide and has a transition point of 330° C. or lower.

### Advantageous Effects of Invention

According to this invention, the gas barrier property can be improved.

### BRIEF DESCRIPTION OF DRAWINGS

FIG. 1 is an example of a schematic cross-sectional view of a composite member

FIG. 2 is an example of a schematic cross-sectional view of a composite member

FIG. 3 is an example of a schematic cross-sectional view of a composite member

FIG. 4 is an example of a DTA curve obtained by differential thermal analysis (DTA) of an oxide glass

FIG. 5 shows examples of transmittance curves of an oxide glass

FIG. 6 is an example of a schematic cross-sectional view of a solar battery module

FIG. 7 is an example of a schematic cross-sectional view of an organic light-emitting diode (OLED) display

FIG. 8 is an example of a schematic cross-sectional view of a blade for a wind power generator

FIG. 9 is an example of a schematic cross-sectional view of a package electronic component

### DESCRIPTION OF EMBODIMENTS

This invention is explained below.

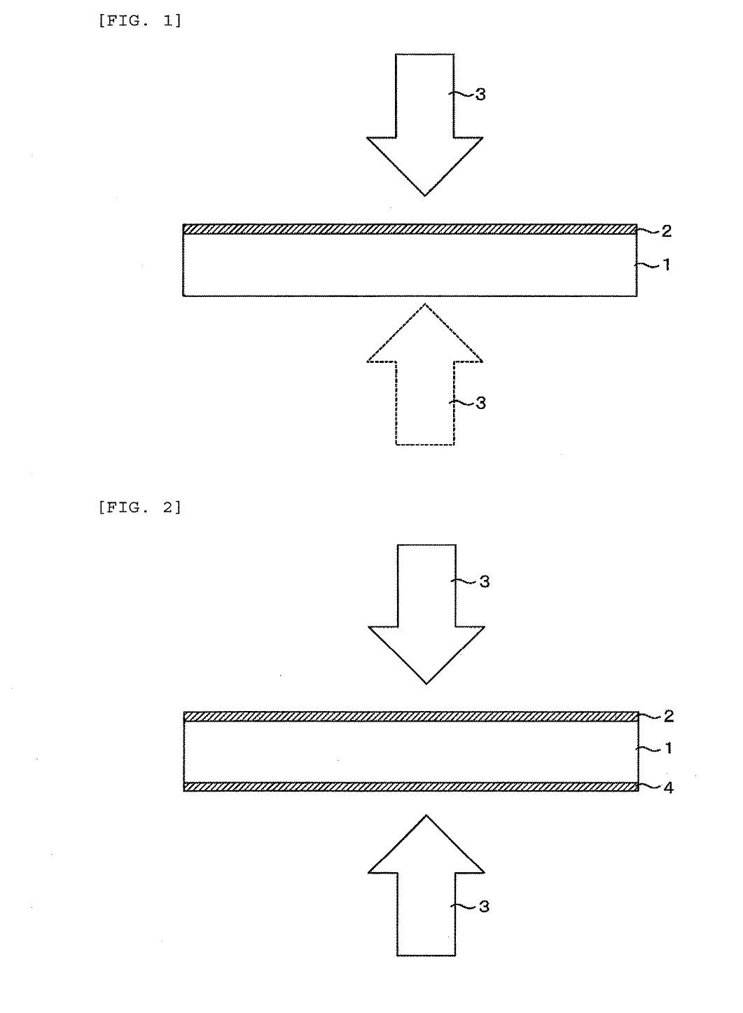

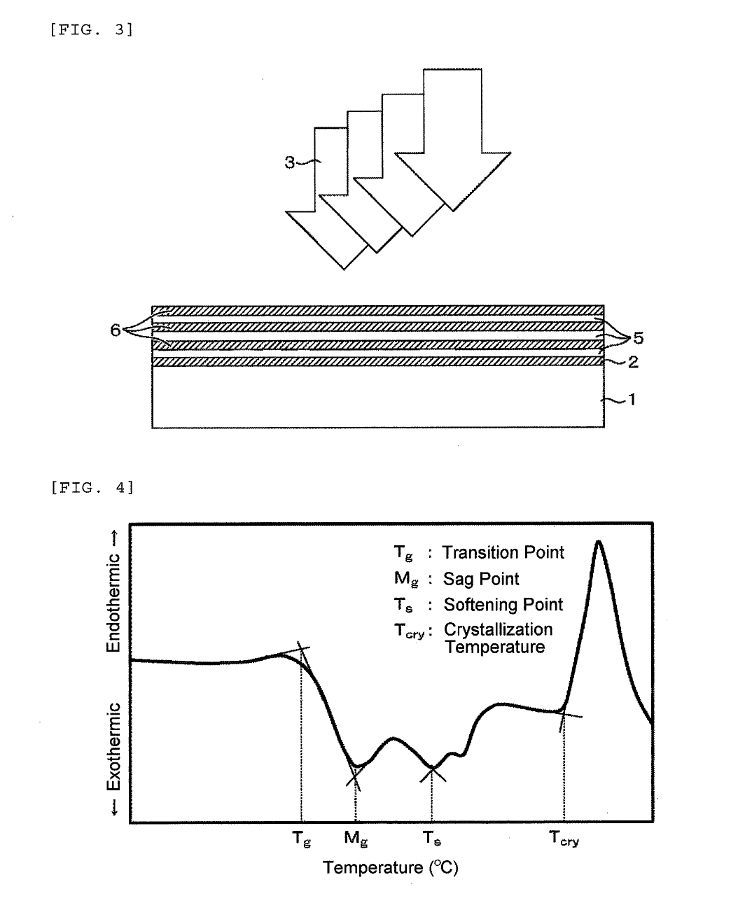

Schematic cross-sectional views of the composite members of the embodiments in this invention are shown in FIG. 1 to FIG. 3. FIG. 1 shows a composite member containing an oxide glass 2 formed as a layer densely on a base material 1 containing a resin or a rubber, in which the oxide glass 2 has been softened and fluidized by irradiating the oxide glass 2 with an electromagnetic wave 3 and solidly bonded and adhered to the base material 1. Further, the electromagnetic wave 3 may be applied from the base material 1 side. FIG. 2 shows a composite member in which oxide glass 2 and 4 have been softened and fluidized by irradiating the oxide glass 2 and 4 with the electromagnetic wave 3 as in FIG. 1 on both surfaces of the base material 1 containing a resin or a rubber and solidly bonded and adhered to the base material 1. FIG. 3 shows a composite member in which an oxide glass 6 has been further sequentially formed and multi-layered through a resin or rubber layer 5 by applying an electromagnetic wave. Here, an important point in the composite members shown in FIG. 1 to FIG. 3 is that the oxide glass 2, 4 and 6 applied to this invention efficiently absorbs the wavelength of the electromagnetic wave 3 and is easily softened and fluidized. When an oxide glass powder is softened, the spaces between the powder particles are filled and thus the coated film becomes a dense layer resulting in the improvement of the gas barrier property. Further, because the oxide glass once melts, the oxide glass can be solidly bonded and adhered to the base material 1 containing a resin or a rubber. In addition, because only an electromagnetic wave is applied, the film can be formed in a shorter time than vapor deposition method, sputtering method, CVD method and the like and a vacuum apparatus or the like is not necessary.

However, in case of an oxide glass which does not absorb an electromagnetic wave or an oxide glass which is softened and fluidized only by a high-power electromagnetic wave, there are sometimes problems in that a layered and dense oxide glass cannot be formed or the thermal damage to the base material containing a resin or a rubber is significant. As the electromagnetic wave 3, a laser having a wavelength in the range of 400 to 1100 nm and a microwave having a wavelength in the range of 0.1 to 1000 mm are effective. If the wavelength of the laser is less than 400 nm, there is a possibility that the resin or the rubber contained in the base material 1 deteriorates. On the other hand, with the wavelength exceeding 1100 nm, the oxide glass may not show excellent softness and fluidity or the resin or the rubber contained in the base material 1 may become hot and melt if a tiny amount of water is included in the resin or the rubber. With the irradiation with a microwave having a wavelength in the range of 0.1 to 1000 mm, the oxide glass obtains semiconductor-like conductivity, and thus the oxide glass can absorb the electromagnetic wave thereof and can be softened and fluidized as with the irradiation with the laser above. Accordingly, the oxide glass can be solidly bonded and adhered to the base material 1. The source of the microwave is not particularly limited and those of 2.45 GHz band and the like which are used for a known microwave for domestic use and the like can be used.

In addition, in the composite member of this invention, the average thickness of each layer of the oxide glass is preferably 50 μm or less. When this average thickness is 50 μm or less, the oxide glass can be excellently softened and fluidized. The softening and fluidizing mechanism of the oxide glass is as follows: the surface part of the oxide glass irradiated with the electromagnetic wave first starts to be softened and fluidized; the heat thereof transfers in the depth (thickness) direction; and the electromagnetic-wave-irradiated part is softened and fluidized as a whole. Therefore, if the thickness of the oxide glass is large, it becomes difficult to efficiently and evenly soften and fluidize in the electromagnetic-wave-irradiation direction. The particularly effective average thickness range of the oxide glass was 3 to 20 μm. When the average thickness was 20 μm or less, the oxide glass could be easily softened and fluidized with the irradiation with the electromagnetic wave and a composite member in which a layered and dense oxide glass was formed was easy to obtain. However, when the average thickness was less than 3 μm, the thickness was so small that an even layered film was difficult to obtain although the oxide glass was softened and fluidized.

Moreover, the oxide glass in the composite member of this invention preferably contains a transition metal oxide and has a transition point of 330° C. or lower. When a transition metal oxide is contained, the oxide glass absorbs the above electromagnetic wave and thus becomes easier to soften and fluidize. Further, when the transition point is 330° C. or lower, the softening and fluidization are achieved at a low temperature and the film can be easily formed on the base material. A more specific example of the oxide glass is an oxide glass containing vanadium oxide, tellurium oxide and phosphorus oxide in which, in terms of the following oxides, the total amount of V₂O₅, TeO₂ and P₂O₅ is 70 to 95% by mass and V₂O₅>TeO₂≧P₂O₅ (% by mass). When V₂O₅ as a transition metal oxide is contained most, the electromagnetic wave is easily absorbed. TeO₂ and P₂O₅ are contained for glass formation and P₂O₅ is more effective than TeO₂ for glass formation while TeO₂ is more effective than P₂O₅ for softening and fluidizing at a lower temperature. As a result, it is more effective that both are contained and the relation is TeO₂P₂O₅ as % by mass. Further, it is effective that the total amount of V₂O₅, TeO₂ and P₂O₅ is 70 to 95% by mass and the softening and fluidization by the irradiation with the electromagnetic wave become not so easy if the total amount is less than 70% by mass. On the other hand, if the total amount exceeds 95% by mass, the reliability such as moisture resistance and water resistance tends to deteriorate. In this regard, in this invention, when the amount is described to be 70 to 95% by mass for example, it means that the amount is 70% by mass or more and 95% by mass or less.

Further, it is desirable that the above oxide glass contains one or more kinds of iron oxide, tungsten oxide, molybdenum oxide, manganese oxide, antimony oxide, bismuth oxide, barium oxide, potassium oxide and zinc oxide in addition to vanadium oxide, tellurium oxide and phosphorus oxide. By containing these oxides, the reliability such as moisture resistance and water resistance can be improved and the tendency towards the crystallization can be lowered. The most effective glass compositional range is, in terms of the following oxides, 35 to 55% by mass of V₂O₅, 15 to 35% by mass of TeO₂, 4 to 20% by mass of P₂O₅ and 5 to 30% by mass of one or more kinds of Fe₂O₃, WO₃, MoO₃, MnO₂, Sb₂O₃, Bi₂O₃, BaO, K₂O and ZnO. If the amount of V₂O₅ is less than 35% by mass, the softening and fluidization by the irradiation with the electromagnetic wave become not so easy. On the other hand, if the amount exceeds 55% by mass, the reliability such as moisture resistance and water resistance deteriorates. If the amount of TeO₂ is less than 15% by mass, the tendency towards the crystallization becomes significant, the transition point increases and the reliability such as moisture resistance and water resistance deteriorates. On the other hand, if the amount exceeds 35% by mass, although the temperature can be lowered, the softening and fluidization by the irradiation with the electromagnetic wave become difficult. If the amount of P₂O₅ is less than 4% by mass, the tendency towards the crystallization becomes significant and the softening and fluidization by the irradiation with the electromagnetic wave become difficult. On the other hand, if the amount exceeds 20% by mass, the transition point increases and the softening and fluidization become not so easy even when the electromagnetic wave is applied. Furthermore, the reliability such as moisture resistance and water resistance deteriorates. If the amount of one or more kinds of Fe₂O₃, WO₃, MoO₃, MnO₂, Sb₂O₃, Bi₂O₃, BaO, K₂O and ZnO is less than 5% by mass, the effects for improving the reliability such as moisture resistance and water resistance, decreasing the tendency towards the crystallization and the like are hardly obtained. On the other hand, if the amount exceeds 30% by mass, these effects rather affect adversely and the softening and fluidization become not so easy even when the electromagnetic wave is applied.

The composite member of this invention shown in FIG. 1 is obtained by a manufacturing method containing a step of spray-coating slurry containing a powder of the oxide glass 2 or print-coating paste thereof on the base material 1 containing a resin or a rubber and a step of softening and fluidizing the powder of the oxide glass 2 by applying the electromagnetic wave 3 and forming a layered and dense fired coated film on the base material. The oxide glass powder may be prepared as a fluid liquid (slurry, paste or the like) and coated on the base material. In the composite member of this invention shown in FIG. 2, the oxide glass 4 is formed on the other surface of the base material 1 as in FIG. 1 above. The composite member of this invention shown in FIG. 3 is obtained by a manufacturing method containing a step of coating the resin or rubber layer 5 on the fired coated film of the oxide glass 2 shown in FIG. 1, a step of spray-coating slurry containing a powder of the oxide glass 6 or print-coating paste thereof on the resin or rubber layer, a step of softening and fluidizing the powder of the oxide glass 6 by applying the electromagnetic wave and forming a layered and dense fired coated film on the base material 1, and a step of repeating these steps for one or more times and multi-layering the fired coated film of the oxide glass 6. Here, the particularly effective electromagnetic wave 3 is a laser having a wavelength in the range of 400 to 1100 nm.

The composite member of this invention can be applied as a window of a house or a car; when slurry containing a powder of the oxide glass is spray-coated or paste thereof is print-coated on one surface or both surfaces of a transparent resin base plate, the oxide glass powder is softened and fluidized by applying a laser having a wavelength in the range of 400 to 1100 nm and a fired coated film having an average thickness of 3 to 20 μm is formed on the resin base plate. A glass plate, which has high reliability, has been conventionally used for such a window; however, there were problems in that a glass plate was heavy and dangerous when it broke. By this invention, a window which is light and does not break easily can be provided. In addition, because the oxide glass is formed as a layer densely in the window of this invention, the moisture absorption and deterioration by ultraviolet rays of the resin base plate hardly occur and the surface hardness can be also improved, thereby ensuring the reliability comparable to that of a glass base plate. Moreover, this invention can be also developed into a base material of a solar battery module or an image display device, when it is formed as described above on a transparent resin base plate or resin film, and it becomes possible to provide a solar battery module and an image display device which are light and have high reliability.

Further, in this invention, it is possible to coat a coating material containing an oxide glass powder on the surface of a fiber-reinforced blade used for a wind power generator, soften and fluidize the oxide glass powder by applying a laser having a wavelength in the range of 400 to 1100 nm, and form a fired coated film having an average thickness of 10 to 50 μm on the surface of the blade. Thus, it is possible to provide a blade for a wind power generator with high reliability in which the moisture absorption and the deterioration by ultraviolet rays of the blade are prevented and the blade is not likely to be scratched due to the hard coating of the oxide glass.

In addition, in this invention, it is possible to spray-coat slurry containing an oxide glass powder or print-coat paste thereof on inner surfaces or outer surfaces of a cap and a base plate made of a rein, soften and fluidize the oxide glass powder by applying a laser having a wavelength in the range of 400 to 1100 nm, form a fired coated film having an average thickness of 3 to 20 provide an element on the base plate, put a cap, and irradiate the periphery with the laser for sealing. Thus, it is possible to develop this invention into a package electronic component which requires high gas barrier property.

Further, in this invention, it is possible to spray- or print-coat slurry or paste containing a powder of the above oxide glass on the surface of a resin panel provided in a food storage such as a refrigerator, soften and fluidize the oxide glass powder by applying a laser having a wavelength in the range of 400 to 1100 nm, and form a fired coated film having an average thickness of 3 to 20 μm. Thus, it is possible to provide a panel for a food storage which is unlikely to absorb moisture and odor.

Although the method for producing the oxide glass of this invention is not particularly limited, the oxide glass can be produced by introducing the materials, in which all oxides as raw materials have been incorporated and mixed, in a platinum crucible, heating to 900 to 950° C. in an electric furnace with a rate of temperature increase of 5 to 10° C./minute and keeping for several hours. During the materials are kept, it is desirable to stir the materials in order to obtain homogeneous glass. When the crucible is taken out from the electric furnace, it is desirable to pour the oxide glass into a graphite mold or onto a stainless plate which has been previously heated to around 150° C. in order to prevent the water adsorption of the oxide glass surface.

The resin or the rubber in this invention is not particularly limited, and both crystalline and amorphous ones can be used and not only one kind but also a combination of several kinds can be used. For example, polyethylene, polyvinyl chloride, polypropylene, polystyrene, polyvinyl acetate, ABS resin, AS resin, acrylic resin, phenolic resin, polyacetal resin, polyimide, polycarbonate, modified polyphenylene ether (PPE), polybutylene terephthalate (PBT), polyarylate, polysulfone, polyphenylene sulfide, polyetheretherketone, polyimide resin, fluorine resin, polyamide-imide, polyetheretherketone, epoxy resin, polyester, polyvinyl ester, fluorine-containing rubber, silicone rubber, acrylic rubber and the like can be used. However, because the oxide glass is softened and fluidized by the irradiation with the electromagnetic wave while it is in contact with the resin or the rubber, the heatproof temperature of the resin or the rubber is preferably as high as possible. If the heatproof temperature of the resin is significantly lower than the transition point of the oxide glass, there is a risk that the resin or the rubber burns due to the oxide glass heated by the irradiation with the electromagnetic wave.

From the above, the composite member of this invention and a product using it maintain the advantages of an organic compound, such as the lightness and the formability at a low temperature, and can also compensate the defects such as the low gas barrier property, absorbency, odor-absorbing property, deterioration by the irradiation with ultraviolet rays and low mechanical strength (softness).

Further details are explained below using Examples. However, this invention is not limited by the descriptions of the Examples mentioned here and the Examples can be appropriately combined.

### Example 1

In this Example, using a polycarbonate base plate as the base material and, in terms of the following oxides, 47V₂O₅-30TeO₂-13P₂O₅-10Fe₂O₂ (% by mass) as the oxide glass, a test of the electromagnetic wave irradiation was conducted. As the electromagnetic wave, semiconductor lasers having wavelengths of about 400 nm, 600 nm and 800 nm were used.

The oxide glass was produced by incorporating and mixing certain amounts of reagents V₂O₅, TeO₂, P₂O₅ and Fe₂O₃ manufactured by Kojundo Chemical Laboratory Co., Ltd. in a total amount of 200 g, introducing the mixture into a platinum crucible, heating to 900 to 950° C. in an electric furnace with a rate of temperature increase of 5 to 10° C./minute and melting. In order to obtain homogeneous glass, the mixture was kept at this temperature for one to two hours while it was stirred. Then, the crucible was taken out and the glass was poured onto a stainless plate which had been previously heated to about 150° C.

The glass poured onto the stainless plate was pulverized into a powder having an average particle diameter (D₅₀) of less than 20 μm, and the transition point (T_{g}), the sag point (M_{g}), the softening point (Tₛ) and the crystallization temperature (T_{cry}) were measured by conducting differential thermal analysis (DTA) up to 550° C. with a rate of temperature increase of 5° C./minute. In this regard, an alumina (Al₂O₃) powder was used as the standard sample. A typical DTA curve of the oxide glass is shown in FIG. 4. As shown in FIG. 4, T_{g} was the onset temperature of the first endothermic peak, M_{g} was the peak temperature thereof, Tₛ was the peak temperature of the second endothermic peak and T_{cry} was the onset temperature of a significant exothermic peak by the crystallization. T_{g} of the oxide glass made from 47V₂O₅-30TeO₂-13P₂O₅-10Fe₂O₃ (% by mass) was 293° C., M_{g} was 314° C. and Tₛ was 364° C. T_{cry} was not observed with DTA up to 550° C. That is, it was suggested that this oxide glass was difficult to crystallize. The crystallization causes the deterioration of the softness and fluidity and it is thus important to control or prevent the crystallization. It is effective that T_{cry} is higher than T_{g}, M_{g} and Tₛ if possible.

The moisture resistance of the oxide glass made from 47V₂O₅-30TeO₂-13P₂O₅-10Fe₂O₃ (% by mass) was excellent. The moisture resistance was evaluated under the condition of the temperature of 85° C. and the humidity of 85% for seven days. A prismatic column of 4×4×20 mm was used as the evaluation sample and the sample was evaluated as “A” when no change in the appearance was observed or as “C” when change was observed. The oxide glass above was “A”.

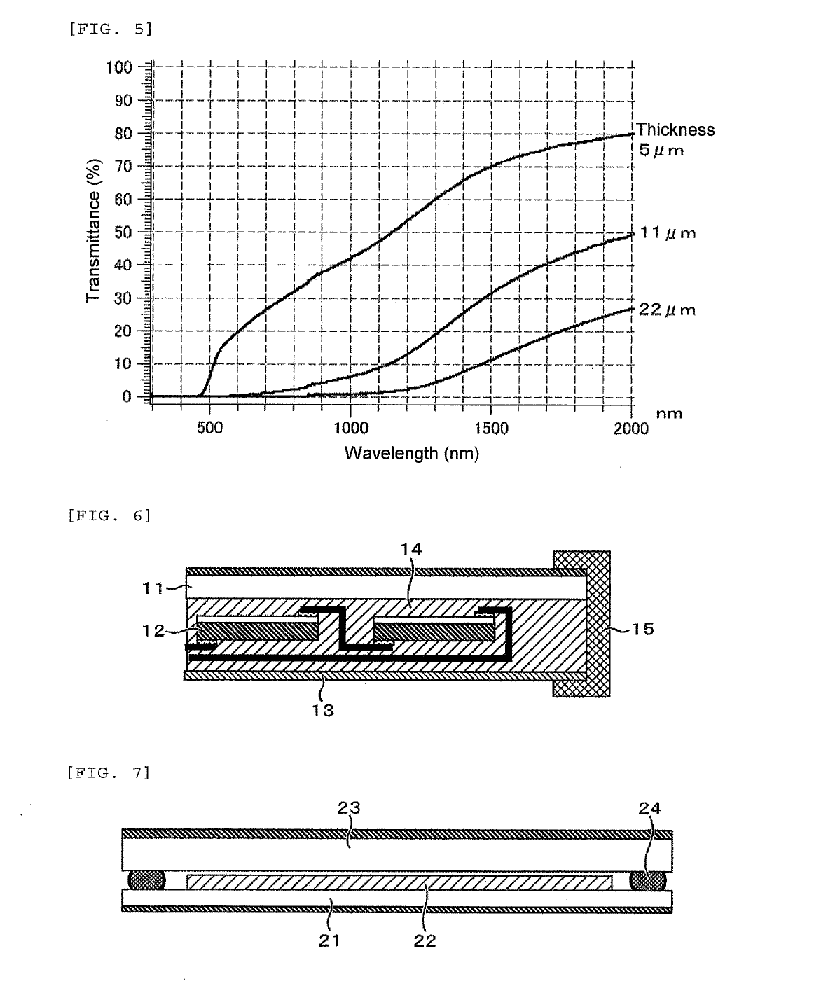

The optical characteristics of the oxide glass made from 47V₂O₅-30TeO₂-13P₂O₅-10Fe₂O₃ (% by mass) were evaluated by the transmittance using an ultraviolet and visible spectrophotometer. As the evaluation sample, paste for printing was produced by pulverizing the oxide glass produced into a powder having an average particle diameter (D₅₀) of 2 μm or less with a jet mill, introducing a solvent in which a 4% resin binder was dissolved to the glass powder and mixing. Here, ethyl cellulose was used as the resin binder and butyl carbitol acetate was used as the solvent. This paste was coated on glass slides by screen-printing, dried at 150° C. and then fired in the atmosphere at 400° C. As the firing temperature profile, a two-step profile was used and the resin binder was volatilized and removed by first heating to 350° C. with a rate of temperature increase of 10° C./minute and keeping for 30 minutes. Then, by heating to 400° C. also with a rate of temperature increase of 10° C. and keeping for 10 minutes, fired coated films of the oxide glass were obtained. The viscosity of the paste and the printing method were controlled so that the average thicknesses of the fired coated films became about 5 μm, 10 μm and 20 μm. Regarding the fired coated films formed on the glass slides, transmittance curves in the wavelength range of 300 to 2000 nm were measured using an ultraviolet and visible spectrophotometer. In this regard, the transmittance curve of the glass slide only was subtracted as the base line so as to obtain the transmittance curves as close to those of the fired coated films of the oxide glass only as possible. The transmittance curves of the oxide glass made from 47V₂O₅-30TeO₂-13P₂O₅-10Fe₂O₃ (% by mass) regarding various thicknesses are shown in FIG. 5. In the wavelength range of 300 to 2000 nm, the smaller the wavelength is, the smaller transmittance this oxide glass has, and this oxide glass hardly transmits ultraviolet rays having a wavelength of less than 400 nm. This is very effective for forming on a resin or a rubber which deteriorates by ultraviolet rays. Further, there is a risk that a resin or a rubber absorbs a wavelength exceeding 1100 nm if it includes a tiny amount of water; however, the fired coated film of the oxide glass has appropriate absorption in 1100 nm or less and a laser having a wavelength in the range of 400 to 1100 nm can be applied. Moreover, the larger the thickness of the fired coated film of the oxide glass was, the more significantly the transmittance decreased. It is necessary to decide the thickness considering the transmittance, the gas barrier property and the like.

Using the above sample for optical evaluation, the electrical resistance of the fired coated film of the oxide glass made from 47V₂O₅-30TeO₂-13P₂O₅-10Fe₂O₃ (% by mass) was measured. The measurement was conducted at room temperature by a four-terminal method; the specific resistance was 5.3×10⁶ Ω·cm and semiconductor-like conductivity was observed.

In the test of the electromagnetic wave irradiation, the oxide glass was pulverized into a powder having an average particle diameter (D₅₀) of 2 μm or less with a jet mill and used as described above. By introducing a solvent in which a 1% resin binder was dissolved to the glass powder and mixing, slurry for spraying was produced. Here, ethyl cellulose was used as the resin binder and butyl carbitol acetate was used as the solvent. This slurry was evenly sprayed on a polycarbonate base plate and dried at about 70° C. Then, semiconductor lasers having wavelengths of about 400 nm, 600 nm and 800 nm were each applied. Regarding the irradiation method, by moving the heads of the lasers, the composite member shown in FIG. 1 was obtained. The oxide glass was softened and fluidized and solidly bonded and adhered to the polycarbonate base plate by the irradiation with each laser. When a laser was applied from the base plate side, similar results were obtained. By spraying for several times, the thickness dependency of the oxide glass was evaluated. Study was conducted in such a way that the average thicknesses of the oxide glass fell within the range of 1 to 70 μm. Although an even layer was not obtained when the average thickness was less than 3 μm, an even layered and dense film could be solidly bonded and adhered to the polycarbonate base plate when the average thickness was in the rage of 3 to 20 μm. However, when the average thickness exceeded 20 μm, the adhesiveness to the polycarbonate base plate deteriorated. Thus, a laser was applied from the front surface and the back surface of the polycarbonate base plate. As a result, the film could be solidly bonded and adhered with an average thickness of up to 50 μm and an even layered and dense oxide glass film could be formed. Although semiconductor lasers were used in this Example, it goes without saying that a laser with a high output power can be used for a thicker film. However, a high output power laser apparatus is expensive while a semiconductor laser apparatus is inexpensive.

Next, the composite member shown in FIG. 2 was produced as described above. The oxide glass made from 47V₂O₅-30TeO₂-13P₂O₅-10Fe₂O₃ (% by mass) was evenly spray-coated on both front and back surfaces of a polycarbonate base plate as described above and dried. A semiconductor laser of about 800 nm was applied from both surfaces and the powder of the oxide glass was softened and fluidized to form an even fired coated film thereof. The average thickness of the fired coated film was 7 μm. Further, the fired coated film was even and had a dense layered structure. In addition, the film was solidly bonded and adhered to the polycarbonate base plate.

Next, the composite member shown in FIG. 3 was produced as described above. Slurry of the oxide glass made from 47V₂O₅-30TeO₂-13P₂O₅-10Fe₂O₃ (% by mass) was evenly spray-coated on the surface of a polycarbonate base plate as described above and dried. A semiconductor laser of about 800 nm was applied and the powder of the oxide glass was softened and fluidized to form an even fired coated film thereof. Further, a phenolic resin was coated on the fired coated film and cured by blowing warm air at about 100° C. The slurry of the oxide glass was evenly coated thereon as described above and dried and then an even fired coated film of the oxide glass was formed by applying a semiconductor laser of about 800 nm. By repeating this, layers of the fired coated film of the oxide glass were laminated. The average thickness of each layer was 5 to 10 μm. Further, each fired coated film was even and had a dense layered structure. In addition, even when the films were laminated, the films were solidly bonded and adhered to the polycarbonate base plate and the phenolic resin.

### Example 2

As in Example 1, the oxide glass made from 47V₂O₅-30TeO₂-13P₂O₅-10Fe₂O₃ (% by mass) was formed on base plates and films of polyimide, polyamide-imide, polyarylate, polysulfone, epoxy resin, fluorine resin, fluorine-containing rubber, silicone rubber and acrylic rubber, instead of the polycarbonate base plate, and the composite members as shown in FIG. 1 were produced. As the electromagnetic wave applied, a semiconductor laser having a wavelength of about 800 nm was used. Regarding all the base plates and films, the oxide glass of this Example became an even dense and layered film as in Example 1. The average thicknesses were 3 to 10 μm. Further, the films were solidly bonded and adhered.

Next, a fluorine resin base plate on which slurry of the oxide glass was coated and dried was irradiated with a microwave of 2.45 GHz band (wavelength: 125 mm) using a μReactor manufactured by Shikoku Instrumentation CO., Inc. and the composite member of FIG. 1 was produced. As with the laser irradiation above, this oxide glass could be softened and fluidized and an even and dense layered film was obtained. The average thickness here was 9 μm. Further, the film was solidly bonded and adhered to the fluorine resin base plate. Because the oxide glass has a specific resistance of 5.3×10⁶ Ωcm at room temperature as described in Example 1 and has semiconductor-like conductivity, the oxide glass absorbs a microwave of 2.45 GHz band (wavelength: 125 mm) and can be softened and fluidized. From this result, it goes without saying that the oxide glass can be softened and fluidized also with a microwave having a wavelength in the range of 0.1 to 1000 mm as represented by 2.45 GHz band.

### Example 3

Layers of the oxide glass made from 47V₂O₅-30TeO₂-13P₂O₅-10Fe₂O₃ (% by mass) having different thicknesses were formed on a polyimide film having a thickness of 25 μm as in Example 1, and composite members as shown in FIG. 1 were produced. As the electromagnetic wave applied, a semiconductor laser having a wavelength of about 800 nm was used and the average thicknesses of the oxide glass produced were 2 μm, 3 μm, 5 μm and 8 μm. Using these films, the moisture vapor transmission rate was evaluated. Further, as a comparison, the above polyimide film alone and those in which a SiO₂ film was formed on the polyimide film by sputtering method or sol-gel method were also evaluated. The SiO₂ film thicknesses thereof were each 50 nm. The moisture vapor transmission rates were measured according to JIS K7129 B method (infrared sensor method) under the condition of the temperature of 40° C. and the humidity of 90% RH. The evaluation results of the moisture vapor transmission rate are shown in Table 1.

In Comparative Example a, in which the polyimide film alone was used, the moisture vapor transmission rate was high. On the other hand, with the polyimide films of Comparative Examples b and c in which a SiO₂ film was formed by sputtering method or sol-gel method, the moisture vapor transmission rates were decreased but the gas barrier property was not excellent. It is thought that this is because of the small thicknesses. In addition, it is thought that, because Comparative Example c was not completely mineralized and an organic material was contained a little, the moisture vapor transmission rate thereof was higher than that of Comparative Example b.

In comparison to Comparative Examples a, b and c, the moisture vapor transmission rates could be significantly decreased in Examples A, B, C and D. In particular, in Examples B, C and D, in which the average thicknesses of the oxide glass were 3 μm or more, the moisture vapor transmission rate was hardly observed and it can be said that the gas barrier property was almost perfect. It is thought that such excellent gas barrier property was obtained because the oxide glass was softened and fluidized by the irradiation with the electromagnetic wave and bonded and adhered to the polyimide film as an even and dense layer. It is thought that the gas barrier property of Example A was inferior to those of Examples B, C and D because the homogeneity deteriorated due to the smaller average thickness. Even if the average thickness is small, it is certain that the gas barrier property improves when a dense layer can be evenly formed. For this, it is effective to decrease the particle diameter of the oxide glass powder.

TABLE 1

| | | | | | Moisture Vapor |
|---|---|---|---|---|---|
| | | Film Formed on | Average | | Transmission Rate |
| No. | | Polyimide Film | Thickness | | (g/m²/day) |
| Example | A | Oxide Glass | 2 | μm | 5 |
| | B | Oxide Glass | 3 | μm | <1 |
| | C | Oxide Glass | 5 | μm | <1 |
| | D | Oxide Glass | 8 | μm | <1 |
| Comparative | a | None | 0 | | 89 |
| Example | b | SiO₂ Film | 50 | nm | 17 |
| | | (Sputtering Method) | | | |
| | c | SiO₂ Film | 50 | nm | 32 |
| | | (Sol-Gel Method) | | | |

### Example 4

In this Example, the composition and characteristics of the oxide glass were studied. The compositions and characteristics of the oxide glass studied are shown in Table 2. As the glass raw materials, reagents V₂O₅, TeO₂, P₂O₅, Fe₂O₃, WO₃, MoO₃, MnO₂, Sb₂O₃, Bi₂O₃, BaCO₃, K₂CO₃ and ZnO manufactured by Kojundo Chemical Laboratory Co., Ltd. were used and the oxide glass was produced as in Example 1. The transition point of the oxide glass produced was measured by DTA as in Example 1. Further, the water resistance was evaluated also as in Example 1. An oxide glass powder was pressed and formed by hand pressing; a titanium sapphire laser (wavelength: 808 nm), a YAG laser (wavelength: 1064 nm) and a microwave of 2.45 GHz band (wavelength: 125 mm) were each applied; and the softness and fluidity of the oxide glass produced was evaluated as “A” when the oxide glass could be fluidized, as “B” when it could be softened and as “C” when it could not be fluidized nor softened.

As it is seen from Examples G12, 14, 15, 17, 20-25, 27-30, 33, 35-37 and 39-48 in Table 2, the samples with excellent moisture resistance satisfied the relation V₂O₅>TeO₂≧P₂O₅ (% by mass) and the total amounts of the oxides were 70% by mass or more and 95% by mass or less. Here, the transition points of the oxide glass were 330° C. or lower and the moisture resistance properties were also excellent. Furthermore, the softness and fluidity properties by the irradiation with the electromagnetic waves such as the lasers and the microwave were also excellent and it is possible to produce the composite members shown in FIG. 1 to FIG. 3. The compositional range of V₂O₅ of 35 to 55% by mass, the compositional range of TeO₂ of 15 to 35% by mass, the compositional range of P₂O₅ of 4 to 20% by mass and the compositional range of one or more kinds of Fe₂O₃, WO₃, MoO₃, MnO₂, Sb₂O₃, Bi₂O₃, BaO, K₂O and ZnO of 5 to 30% by mass were effective.

TABLE 2

| Glass | Composition (% by mass) | | | | | | | | | | | |
|---|---|---|---|---|---|---|---|---|---|---|---|---|
| No. | V₂O₅ | TeO₂ | P₂O₅ | Fe₂O₃ | WO₃ | MoO₃ | MnO₂ | Sb₂O₃ | Bi₂O₃ | BaO | K₂O | ZnO |
| G1 | 65 | 15 | 20 | | | | | | | | | |
| G2 | 65 | 10 | 20 | 5 | | | | | | | | |
| G3 | 65 | | 20 | | | | 10 | | | 5 | | |
| G4 | 65 | 5 | 20 | 5 | | | 5 | | | | | |
| G5 | 65 | 5 | 20 | | | | 10 | | | | | |
| G6 | 65 | 5 | 20 | | | | 7 | | | | | 3 |
| G7 | 65 | 5 | 20 | | 5 | | 5 | | | | | |
| G8 | 60 | | 20 | | | | 10 | | | | | 10 |
| G9 | 60 | | 20 | 5 | | | 10 | | | 5 | | |
| G10 | 60 | 5 | 20 | | | | 15 | | | | | |
| G11 | 60 | 10 | 20 | | | | 10 | | | | | |
| G12 | 60 | 20 | 15 | 5 | | | | | | | | |
| G13 | 60 | 25 | 15 | | | | | | | | | |
| G14 | 55 | 25 | 10 | 10 | | | | | | | | |
| G15 | 55 | 20 | 15 | 10 | | | | | | | | |
| G16 | 55 | 5 | 20 | | | | 15 | | | | | |
| G17 | 55 | 20 | 15 | 5 | | | | | | 5 | | |
| G18 | 55 | 15 | 20 | | | | 5 | | | 5 | | |
| G19 | 55 | 15 | 20 | | | | 10 | | | | | |
| G20 | 55 | 20 | 10 | 10 | | | 5 | | | | | |
| G21 | 55 | 20 | 10 | 10 | | | | | | | | 5 |
| G22 | 55 | 20 | 15 | 5 | 5 | | | | | | | |
| G23 | 55 | 20 | 15 | 5 | | 5 | | | | | | |
| G24 | 55 | 20 | 15 | 5 | | | | | | | | 5 |
| G25 | 55 | 20 | 15 | 5 | | | 5 | | | | | |
| G26 | 52 | | 22 | 8 | | | | | | 15 | | 3 |
| G27 | 50 | 20 | 15 | 15 | | | | | | | | |
| G28 | 50 | 25 | 15 | 10 | | | | | | | | |
| G29 | 50 | 20 | 20 | 10 | | | | | | | | |
| G30 | 50 | 20 | 20 | 5 | | | | | | | | 5 |
| G31 | 50 | 5 | 20 | | | | 25 | | | | | |
| G32 | 50 | 10 | 20 | | | | 10 | | | 5 | | 5 |
| G33 | 50 | 20 | 15 | 5 | 5 | | | | | 5 | | |
| G34 | 48 | | 22 | 10 | | | | | | 15 | | 3 |
| G35 | 45 | 20 | 20 | 10 | 5 | | | | | | | |
| G36 | 45 | 20 | 15 | 5 | | | 5 | | | 5 | | 5 |
| G37 | 45 | 20 | 20 | 5 | | 5 | | | | | | 5 |
| G38 | 45 | | 25 | 10 | | | | | | 15 | | 5 |
| G39 | 47 | 30 | 13 | 10 | | | | | | | | |
| G40 | 45 | 20 | 15 | 10 | | | | | | | | |
| G41 | 38 | 30 | 5.8 | | 10 | | | | | 11.2 | 5 | |
| G42 | 55 | 20 | 10 | | | | | 10 | | 5 | | |
| G43 | 50 | 20 | 12 | 8 | 5 | | | 5 | | | | |
| G44 | 50 | 25 | 15 | 10 | | | | | | | | |
| G45 | 50 | 20 | 12 | 8 | | | | | 5 | | | |
| G46 | 40 | 30 | 4 | | 10 | | | | | 11 | 5 | |
| G47 | 50 | 35 | 10 | 5 | | | | | | | | |
| G48 | 35 | 30 | 5 | 5 | 10 | | | | | 10 | 5 | |
| G49 | 30 | 30 | 5 | | 15 | | | | | 15 | 5 | |

| | | | Softness and Fluidity | | | |
|---|---|---|---|---|---|---|
| Glass | Transition Point | Moisture | Titanium | YAG | 2.45 GHz | |
| No. | (° C.) | Resistance Test | Sapphire Laser | Laser | Microwave | |
| G1 | 272 | C | A | A | A | Comparative Example |
| G2 | 275 | C | A | A | A | Comparative Example |
| G3 | 294 | C | A | A | A | Comparative Example |
| G4 | 285 | C | A | A | A | Comparative Example |
| G5 | 286 | C | A | A | A | Comparative Example |
| G6 | 278 | C | A | A | A | Comparative Example |
| G7 | 289 | C | A | A | A | Comparative Example |
| G8 | 288 | C | A | A | A | Comparative Example |
| G9 | 301 | C | A | A | A | Comparative Example |
| G10 | 296 | C | A | A | A | Comparative Example |
| G11 | 298 | C | A | A | A | Comparative Example |
| G12 | 280 | A | A | A | A | Example |
| G13 | 276 | C | A | A | A | Comparative Example |
| G14 | 281 | A | A | A | A | Example |
| G15 | 285 | A | A | A | A | Example |
| G16 | 306 | C | A | A | A | Comparative Example |
| G17 | 285 | A | A | A | A | Example |
| G18 | 301 | C | A | A | A | Comparative Example |
| G19 | 294 | C | A | A | A | Comparative Example |
| G20 | 295 | A | A | A | A | Example |
| G21 | 288 | A | A | A | A | Example |
| G22 | 281 | A | A | A | A | Example |
| G23 | 260 | A | A | A | A | Example |
| G24 | 278 | A | A | A | A | Example |
| G25 | 285 | A | A | A | A | Example |
| G26 | 357 | C | B | B | B | Comparative Example |
| G27 | 295 | A | A | A | A | Example |
| G28 | 294 | A | A | A | A | Example |
| G29 | 305 | A | A | A | A | Example |
| G30 | 300 | A | A | A | A | Example |
| G31 | 325 | C | A | A | A | Comparative Example |
| G32 | 299 | C | A | A | A | Comparative Example |
| G33 | 296 | A | A | A | A | Example |
| G34 | 374 | C | B | B | C | Comparative Example |
| G35 | 302 | A | A | A | A | Example |
| G36 | 317 | A | A | A | A | Example |
| G37 | 305 | A | A | A | A | Example |
| G38 | 384 | C | B | B | C | Comparative Example |
| G39 | 291 | A | A | A | A | Example |
| G40 | 322 | A | A | A | A | Example |
| G41 | 276 | A | A | A | B | Example |
| G42 | 313 | A | A | A | A | Example |
| G43 | 312 | A | A | A | A | Example |
| G44 | 293 | A | A | A | A | Example |
| G45 | 307 | A | A | A | A | Example |
| G46 | 269 | A | A | A | A | Example |
| G47 | 279 | A | A | A | A | Example |
| G48 | 278 | A | A | A | B | Example |
| G49 | 345 | A | C | C | C | Comparative Example |

### Example 5

In this Example, the potential as a window was studied. Using a polycarbonate base plate having a thickness of 3 mm as a transparent resin base plate, the oxide glass of G41 shown in Table 2 was formed on one surface or both surfaces thereof as in Example 1 in such a way that the average thickness became around 5 to 10 μm, and the composite member for a window as shown in FIG. 1 or FIG. 2 was produced. A frequency-doubled YAG laser (wavelength: 532 nm) was used for the irradiation with the electromagnetic wave. Because G41 is excellent in moisture resistance and can block a light having a wavelength of less than 400 nm, it can prevent or control the deterioration of a resin base plate by rain, ultraviolet rays or the like. Further, because the window produced has a specific gravity of about 1.3 g/cm³, which is about the half of that of a general window glass, and does not easily break unlike glass, the window can contribute to significant weight saving for example by reducing the thickness. The window of this invention is highly expected to serve as a new light window with high reliability which maintains the advantages of both resin and glass and compensates the defects of both resin and glass. The window can be developed into a window of a building such as a house and a side or rear window of a car such as an automobile.

### Example 6

In this Example, the potential as a solar battery module was studied. Using a polycarbonate base plate having a thickness of 3 mm as a transparent resin base plate as in Example 5, the oxide glass of G41 shown in Table 2 was formed on one surface thereof as in Example 1 in such a way that the average thickness became around 3 μm, and the composite member for a solar battery module base plate as shown in FIG. 1 was produced. A frequency-doubled YAG laser (wavelength: 532 nm) was used for the irradiation with the electromagnetic wave. The oxide glass of G41 has characteristics in that the transmittance in the visible region can be increased by increasing the laser output power. This is because the vanadium ions in the glass move to the high valence side and thus the absorption in the visible region is largely reduced. Further, form this, the moisture resistance of G41 does not significantly deteriorate or the characteristics in the ultraviolet region do not significantly change. Using the composite member produced, the solar battery module shown in FIG. 6 was produced. FIG. 6 is a schematic cross-sectional view of a solar battery module in which the composite member 11 of this invention was used instead of the front glass plate. Many solar battery cells 12 were connected in series, provided between the composite member 11 and a back sheet 13 and adhered with an EVA sheet 14. The periphery was fixed with an aluminum frame 15 and a solar battery module was produced. With the solar battery module produced, the weight was successfully reduced by about 40% in comparison with the conventional solar battery module using a front glass plate. Further, from this, cost for the base and for construction can be largely reduced. In order to further reduce the weight, it is effective to reduce the thickness of the resin base plate or use a resin film, and it goes without saying that this oxide glass can be easily formed on such a base material using a laser or a microwave.

### Example 7

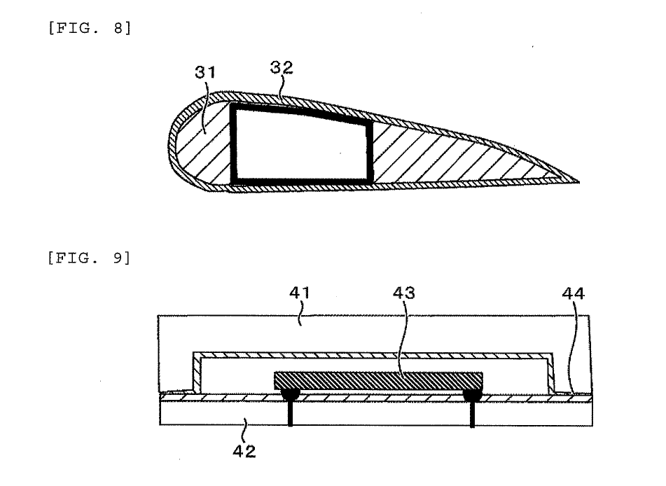

In this Example, the potential as an image display device was studied. A flexible organic light-emitting diode (OLED) display was produced as the image display device. A schematic cross-sectional view of the OLED display produced is shown in FIG. 7. First, the oxide glass G39 in Table 2 was formed on one surface of a polyimide film having a thickness of 25 μm as in Example 2 in such a way that the average thickness became around 5 μm, and the composite member 21 as shown in FIG. 1 was produced. A semiconductor laser having a wavelength of about 800 nm was used for the electromagnetic wave irradiation. An OLED 22 was formed on the other surface of the composite member 21. Next, a composite member 23, in which the oxide glass G41 in Table 2 was formed on a transparent polycarbonate sheet (thickness of 100 μm) as in Example 6 in such a way that the average thickness became around 5 μm, was produced. As shown in FIG. 7, the periphery was airtightly sealed with a sealing material 24.

The OLED display produced was set in wet air at the temperature of 50° C. and the relative humidity of 90% and connected to an alternating-current source of 100 V 400 Hz, and the brightness thereof was measured by lighting it up continuously for 500 hours. The change of the brightness over time was measured but the brightness was scarcely decreased, and the composite member of this invention can be developed into an image display device such as an OLED display.

### Example 8

In this Example, the potential as a blade for a wind power generator was studied. A schematic cross-sectional view of the blade for a wind power generator produced is shown in FIG. 8. A blade 31 has been reinforced with glass fibers or carbon fibers in a resin. The oxide glass 32 according to this invention was formed on the surface thereof by the irradiation with an electromagnetic wave. G23 in Table 2 was used as the oxide glass 32, and the oxide glass was formed on the surface of a resin containing glass fibers or carbon fibers by the irradiation with a titanium sapphire laser (wavelength: 808 nm). The average thickness thereof was studied in the range of 5 to 80 μm. Because the blade surface was rough, it was not possible to evenly form the oxide glass when the average thickness was less than 10 μm. On the other hand, when the average thickness exceeded 50 μm, the oxide glass could not be solidly bonded nor adhered even when the laser output power was increased. From this, it was found that the average thickness is preferably 10 to 50 μm. It is needless to say that the oxide glass is harder than a resin or a rubber and a hard coating with durability can be formed on the blade surface. In addition, the reliability can be further improved by laminating the oxide glass layers through an epoxy resin or the like. Moreover, because the oxide glass according to this invention has conductivity, the damage to the blade due to a thunderbolt can be prevented or controlled, and this invention can be preferably developed into a blade for a wind power generator.

### Example 9

In this Example, the potential as a package electronic component was studied. A schematic cross-sectional view of the package electronic component produced is shown in FIG. 9. The oxide glass G41 in Table 2 was formed on the inside of a cap 41 and a base plate 42 made of a resin by the irradiation with an electromagnetic wave as in Example 1 in such a way that each average thickness became around 10 μm. Polycarbonate was used for the resin cap and the resin base plate. Further, a semiconductor laser having a wavelength of about 600 nm was used for the electromagnetic wave irradiation. An element 43 was provided and fixed on the base plate 42 on which G41 was formed, the cap 41 on which G41 was formed was put, and a joint part 44 was irradiated with the semiconductor laser through the base plate in vacuum and sealed. As a result of a helium leakage test, it was confirmed that the joint part could be airtightly sealed. From this, this invention can be applied to a package electronic component.

### Example 10

In this Example, the potential as a resin panel or the like provided in a food storage such as a refrigerator was studied. An acrylic resin was used as the resin panel. The oxide glass G48 in Table 2 was formed on this resin panel as in Example 1 by the irradiation with an electromagnetic wave in such a way that the average thickness became around 10 μm. A semiconductor laser having a wavelength of about 800 nm was used for the electromagnetic wave irradiation. An odor absorption test of the acrylic resin panel on which G48 was formed was conducted. Odor was absorbed in case of the acrylic resin panel only while the acrylic resin panel on which G48 was formed did not absorb odor, and thus it was found that the panel can be developed into a panel for a food storage such as a refrigerator. Further, from this finding, it goes without saying that the development into a bath-tub, a toilet and the like is also expected. A toilet constituted by a resin or the like may be produced.

### REFERENCE SIGNS LIST

1: Base material containing a resin or a rubber (base material)
2, 4, 6 and 32: Oxide glass
3: Electromagnetic wave
5: Resin or rubber layer
11: Composite member
12: Solar battery cell
13: Back sheet
14: EVA sheet
15: Aluminum frame
21: Back side composite member
22: Organic light-emitting diode (OLED)
23: Front side composite member
24: Sealing material
31: Blade for a wind power generator
41: Resin cap
42: Resin base plate
43: Element
44: Joint part

1. A composite member comprising an oxide glass formed as a layer densely on a base material containing a resin or a rubber, wherein the oxide glass is bonded to the base material by irradiating the oxide glass containing a transition metal oxide with an electromagnetic wave and softening and fluidizing the oxide glass.

2. The composite member described in claim 1, wherein the electromagnetic wave is a laser having a wavelength in the range of 400 to 1100 nm.

3. The composite member described in claim 1, wherein the electromagnetic wave is a microwave having a wavelength in the range of 0.1 to 1000 mm.

4. The composite member described in claim 1, wherein layers of the oxide glass are laminated through the base material.

5. The composite member described in claim 1, wherein the average thickness of each layer of the oxide glass is 50 μm or less.

6. The composite member described in claim 5, wherein the average thickness of each layer of the oxide glass is 3 to 20 μm.

7. The composite member described in claim 1, wherein the transition point of the oxide glass is 330° C. or lower.

8. The composite member described in claim 1, wherein the oxide glass contains a vanadium oxide, a tellurium oxide and a phosphorus oxide, and in terms of the following oxides, the total amount of V₂O₅, TeO₂ and P₂O₅ is 70 to 95% by mass and V₂O₅>TeO₂≧P₂O₅ (% by mass).

9. The composite member described in claim 8, wherein the oxide glass further contains one or more kinds of an iron oxide, a tungsten oxide, a molybdenum oxide, a manganese oxide, an antimony oxide, a bismuth oxide, a barium oxide, a potassium oxide and a zinc oxide.

10. The composite member described in claim 9, wherein the oxide glass contains, in terms of the following oxides, 35 to 55% by mass of V₂O₅, 15 to 35% by mass of TeO₂, 4 to 20% by mass of P₂O₅ and 5 to 30% by mass of one or more kinds of Fe₂O₃, WO₃, MoO₃, MnO₂, Sb₂O₃, Bi₂O₃, BaO, K₂O and ZnO.

11. A method for producing a composite member comprising a step of coating an oxide glass powder on a base material containing a resin or a rubber, a step of applying an electromagnetic wave and a step of forming a layered and dense coated film on the base material by softening and fluidizing the oxide glass powder, wherein the oxide glass contains a transition metal oxide and has a transition point of 330° C. or lower.

12. The method for producing a composite member described in claim 11, wherein layers of the coated film and resin or rubber layers are laminated by containing a step of further coating the resin or rubber layer on the coated film, a step of coating the oxide glass powder on the resin or rubber layer, a step of applying the electromagnetic wave and a step of forming a layered and dense coated film on the resin or rubber layer by softening and fluidizing the oxide glass powder.

13. The method for producing a composite member described in claim 11, wherein the electromagnetic wave is a laser having a wavelength in the range of 400 to 1100 nm.

14. A window comprising the composite member described in claim 1, wherein the base material is a transparent resin and the average thickness of the coated film is 3 to 20 μm.

15. A solar battery module comprising the composite member described in claim 1, wherein the base material is a transparent resin and the average thickness of the coated film is 3 to 20 μm.

16. An image display device comprising the composite member described in claim 1, wherein the base material is a transparent resin and the average thickness of the coated film is 3 to 20 μm.

17. A blade for a wind power generator comprising the composite member described in claim 1, wherein the average thickness of the coated film is 10 to 50 μm.

18. A package electronic component comprising an element provided in a space formed by a base plate and a cap and the composite member described in claim 1 provided at a connection part of the base plate and the cap, wherein the average thickness of the coated film is 13 to 20 μm and the space is sealed by irradiating the composite member with the laser.

19. A panel for a food storage comprising a resin panel provided in the food storage and the composite member described in claim 1, wherein the average thickness of the coated film is 3 to 20 μm.
